(19) United States
(12) Patent Application Publication
(10) Pub. No.: US 2020/0183054 A1
(43) Pub. Date: Jun. 11, 2020

(54) ANTI-REFLECTION COMPOSITE LAYER AND THE MANUFACTURING METHOD THEREOF

(71) Applicant: Institute of Nuclear Energy Research, Atomic Energy Council, Executive Yuan, R.O.C., Taoyuan City (TW)

(72) Inventors: Po-Wen Chen, Taoyuan City (TW); En-Shih Chen, Taoyuan City (TW); Meng-Hsin Chen, Taoyuan City (TW); Jin-Yu Wu, Taoyuan City (TW); Der-Jun Jan, Taoyuan City (TW)

(21) Appl. No.: 16/503,457

(22) Filed: Jul. 3, 2019

(30) Foreign Application Priority Data
Dec. 7, 2018 (TW) 107144212

(51) Int. Cl. G02B 1/115; C23C 14/35

(52) U.S. Cl. CPC G02B 1/115; C23C 14/351

(57) ABSTRACT

An anti-reflection composite layer including a substrate, a plurality of first optical layers and a plurality of second optical layers is provided. The first optical layers and the second optical layers are alternately formed on the carrier surface of the substrate by a PVD coating process, and the refractive index of the materials forming the first optical layers is higher than that of the materials forming the second optical layers. A manufacturing method thereof is also provided.

### TECHNICAL FIELD

The present invention is related to anti-reflection composite layer and the manufacturing method thereof, especially an anti-reflection composite layer manufactured by PVD coating and the manufacturing method thereof.

### BACKGROUND

As optoelectronic display technology develops and the users' demand for user experience increases, the anti-reflection films have been widely used in automotive glass, display devices or photographic devices to reduce the effects of light scattering. The existing high-quality anti-reflection film is mainly manufactured by magnetron sputtering system, however, the rate at which the coating is formed by sputtering is slower (10-40 nanometers per minute) and requires more time. There is also the problem of poisoning the target during the sputtering process, reducing the overall defect-free rate. In addition, the optical monitoring equipment is required, so the cost is increased. Moreover, the required equipment for sputtering is expensive. In terms of the current fabrication technology, it is undoubtedly a major obstacle in the evolution of the field.

### SUMMARY

The present invention proposes a method for fabricating an anti-reflection composite layer, and by improving the fabricating method, the coating rate for manufacturing the anti-reflection film can be elevated and the cost of production can be reduced. And due to high ionizing ability of plasma, the flexible anti-reflection film can be easily disposed on curved surfaces with the fabricating method.

The present invention provides a method for manufacturing anti-reflection composite layer. A high-refractive-index material and a low-refractive-index material are alternately deposited by a PVD coating process to form a composite layer structure, and, by interfering the light within the visible spectrum among the thin optical layers, the reflection in the composite layer is reduced, achieving high transmittance and low reflectance.

The method for manufacturing anti-reflection composite layer provided by the present invention can manufacture anti-reflection layer efficiently.

The anti-reflection composite layer of the present invention includes substrate, first optical layers and second optical layers. The first optical layers and the second optical layers are alternately arranged with each other on the substrate. The substrate has a carrier surface. The second optical layers and the first optical layers are alternately formed on the carrier surface by a PVD coating process, and the refractive index of the materials forming the first optical layers is higher than that of the materials forming the second optical layers.

In an example of the present invention, the melting point of the materials of the first optical layers falls within the range of 1900-3400 degrees Celsius, and the melting point of the materials of the second optical layers falls within the range of 1400-1900 degrees Celsius.

In an example of the present invention, the materials of the first optical layers include TiO₂, WO₃, Ta₂O₅ or Nb₂O₅, and the materials of the second optical layers include SiO₂.

In an example of the present invention, the first optical layers and the second optical layers form into combination layers, each of the combination layers is formed by one of the first optical layers and one of the second optical layers, wherein the second optical layer is formed on the side away from the carrier surface, and the numbers of the combination layers fall within the range of 2-6.

In an example of the present invention, the substrate is flexible glass substrate.

In an example of the present invention, the thickness of each of the first optical layers falls within the range of 5-150 nanometers in the normal direction of the carrier surface, whereas the thickness of each of the second optical layers falls within the range of 5-150 nanometers in the normal direction of the carrier surface.

The method for manufacturing anti-reflection composite layer of the present invention includes: providing a substrate; and forming a plurality of first optical layers and a plurality of second optical layers alternately by a PVD coating process on a carrier surface of the substrate. One of the first optical layers is formed directly on the carrier substrate, and the refractive index of the materials of the first optical layers is higher than that of the second optical layers.

In an example of the present invention, the PVD coating process includes: adjusting pressure of a chamber to a pressure range with suction; placing the substrate into a chamber; forming an electric arc on the surface of a target, causing the target to provide micro ions; and depositing the micro ions to form the first optical layer or the second optical layer, wherein the formation of the first optical layer and the second optical layer respectively correspond to targets of different materials.

In an example of the present invention, the pressure range is less than or equal to 0.001 torr.

In an example of the present invention, after the step of adjusting the pressure of the chamber to the pressure range with suction, oxygen and argon are filled in, wherein the ratio of oxygen to argon falls within the range of 1 to 4.

In an example of the present invention, before the step of forming an electric arc on the target, the method further includes:

forming gradient magnetic field on the surface of the target, wherein the intensity of the magnetic field at the edge of the target is lower than the intensity of the magnetic field in other regions of the target.

In an example of the present invention, the melting point of the materials for forming the first optical layers falls within the range of 1900-3400 degrees Celsius, whereas the melting point of the materials for forming the second optical layers falls within the range of 1400-1900 degrees Celsius.

In an example of the present invention, the materials of the first optical layers include TiO₂, WO₃, Ta₂O₅ or Nb₂O₅; and the materials of the second optical layers include SiO₂.

In an example of the present invention, the first optical layers and the second optical layers form into combination layers, and each of the combination layers is formed by one of the first optical layers and one of the second optical layers, wherein the second optical layer is formed on the side away from the carrier surface, and the numbers of the combination layers fall within the range of 2-6.

As seen from the above, the method for manufacturing anti-reflection composite proposed by the present invention can efficiently manufacture anti-reflection composite layer, and the anti-reflection composite layer proposed by the present invention can provide fine anti-reflection ability.

### BRIEF DESCRIPTION OF DRAWINGS

FIG. 1A is the schematic view of the formation of anti-reflection composite layer in the first example of the present invention;

FIG. 1B is the section view of anti-reflection composite layer of the first example of the present invention.

### DESCRIPTION OF EMBODIMENTS

The present invention proposes an anti-reflection composite layer with fine anti-reflective ability. The anti-reflection composite layer can be disposed on the display surface of the display devices, the lens or display surface of photographic devices as well as on the automotive glass. The present invention is not limited to the application devices of anti-reflection layer.

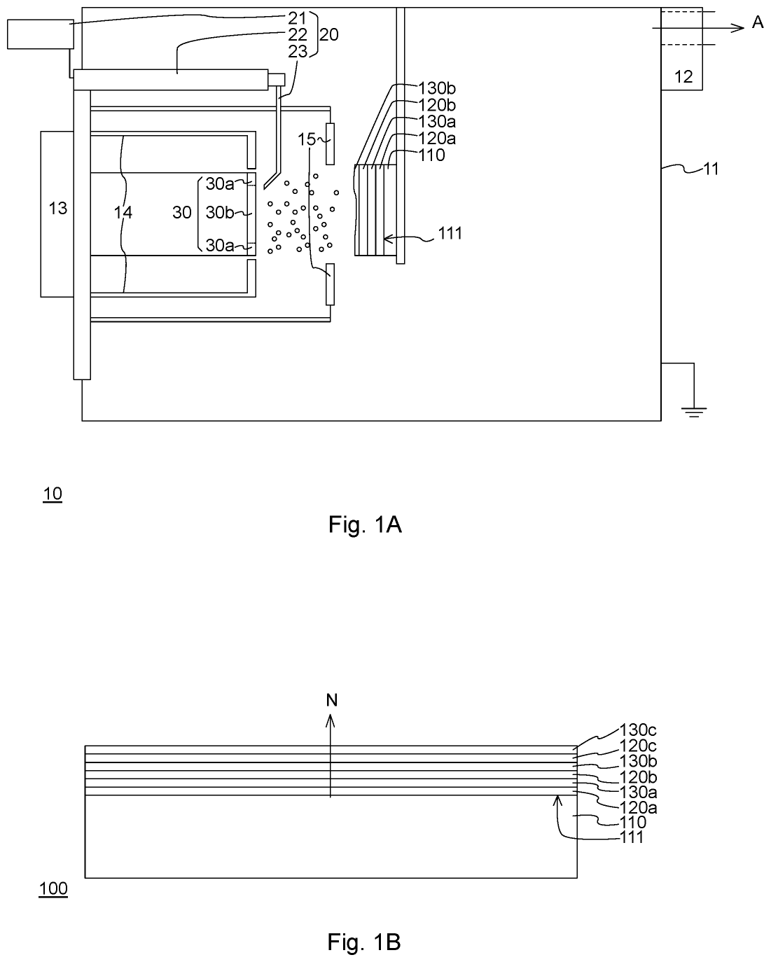

FIG. 1A is the schematic view of the formation of anti-reflection composite layer in the first example of the present invention, wherein to explain explicitly the anti-reflection composite layer and the manufacturing method thereof as proposed by the example of the present invention, part of devices are magnified but are not intended to limit the present invention. Please refer to FIG. 1A, in the first example of the present invention, the formation of anti-reflection composite layer requires first a substrate 110, and first optical layers 120a, 120b and second optical layers 130a, 130b forming on the substrate 110. The first optical layers 120a, 120b and the second optical layers 130a, 130b are formed on the carrier surface 111 of the substrate 110, and are formed alternately on the substrate 110 by a PVD coating process.

To be specific, FIG. 1A here takes the formation of the second layer of the second optical layer 130b on the substrate 110 of the example as instance to elaborate. In the example, the formation of anti-reflection composite layer will place the substrate 110 with the first optical layer 120a, the second optical 130a and the first optical layer 120b on it into the chamber 11 of the coating device 10.

The coating device 10 of the example is, for instance, an arc coating device, preferably a direct current magnetron arc coating device. The coating device 10 includes arc inducing module 20 for forming an electric arc on the target 30. The arc inducing module 20 includes arc-plasma source 21, arc inducer 22 and arc bar 23, wherein part of the arc inducer 22 and arc bar 23 are disposed in the chamber 11 in order to form the electric arc on the surface of the target 30 such that the target 30 generates microparticles that form the second optical layer 130b.

On the other hand, the coating device 10 of the example further includes air extractor 12 which is capable of extracting the chamber 11 to a pressure range, and, preferably, filling oxygen and argon in so that the target 30 can generate microparticles in an appropriate size. For instance, in the coating device 10 of the example, the air extractor 12 can extract the chamber 11 to the vacuum, and then fill oxygen and argon in. Now, the higher the pressure of oxygen and argon in the chamber 11 is, the higher the collision frequency of ion-electron in the plasma, and the smaller the size of the microparticles on the surface of the deposited thin film. Therefore, the air extractor preferably fills a range of pressures ranging from 10 millitorr (mTorr) to 40 mTorr, and the ratio of oxygen to argon falls within the range of 1 to 4 to provide a more suitable environment for generating the microparticles.

The coating device 10 of the example further includes magnetic device 13 for controlling the magnetic field of the target 30. Preferably, the magnetic device 13 can be gradient magnetic field in order to form a stronger magnetic field in the working area 30b of the target 30, and to form a weaker magnetic field in the periphery 30a to elevate the rate of the electric arc on the target 30.

The coating device 10 of the example further includes first arc maintainer 14 and second arc maintainer 15. The first arc maintainer 14 is disposed around the target 30 to remain the target 30 floating and also to limit the range where the electric art is formed. The second arc maintainer 15 provides a passage for the microparticles to be deposited on the substrate 100. The present invention is not limited to the aforementioned device; in other examples, the microparticles can be generated by the electric arc in another setting and form the anti-reflection composite layer on the targeted surface.

In the example, since the coating is formed of the microparticles which are generated by the electric arc on the target 30, the target 30 can be materials with higher melting point. In other words, since the electric arc has higher heating efficiency, the coating can be completed efficiently by the microparticles generated by materials with a high melting point.

The following will make use of the labels from the example above along with other figures to elaborate on the anti-reflection composite layer proposed by the present invention. Please refer to FIG. 1B which is the section view of the anti-reflection composite layer, wherein the anti-reflection composite layer 100 includes substrate 110, first optical layers 120a, 120b, 120c and second optical layer 130a, 130b, 130c forming on the carrier surface 111 of the substrate 110.

In the example, the optical layers are formed alternately on the substrate 110 by arc coating. To be specific, in the anti-reflection composite layer 100 of the example, the first optical layer 120a, the second optical layer 130a, the first optical layer 120b, the second optical layer 130b, the first optical layer 120c, and the second optical layer 130c are formed in order on the carrier surface 111 of the substrate 110, wherein the first optical layer 120a, 120b and 120c are made by materials with higher refractive index, whereas the second optical layer 130a, 130b and 130c are made by materials with lower refractive index. The deposition of the first optical layer 120a, 120b and 120c preferably made of a high refractive index metal oxide by an arc coating process can form a nanoporous structure which makes the characteristic of the anti-reflection composite layer more preferable. The deposition of the second optical layer 130a, 130b and 130c preferable made of a low refractive index metal oxide by an arc coating process can reduce the deposition rate greatly. The coating rate of arc coating method is 5 to 10 times higher than that of the conventional radio frequency (RF) magnetron sputtering method. Therefore, the coating time can be saved greatly.

To be specific, in one embodiment, the material of the first optical layers 120a, 120b and 120c is TiO₂, and the material of the second optical layers 130a, 130b and 130c is SiO2. However, the present invention is not limited to this, in other examples, the material of the first optical layers can be WO₃ or Ta₂O₅, and the materials for the first optical layer and the second optical layer can also be other materials suitable for the arc coating process.

On one hand, in the normal direction N of the carrier surface 111, the thickness of the first optical layers 120a, 120b and 120c falls within the range of 5-150 nanometers, whereas the thickness of the second optical layers 130a, 130b and 130c falls within the range of 5-150 nanometers. Furthermore, since the arc coating rate can reach to 10-40 nanometers per minute, the first optical layers 120a, 120b and 120c as well as the second optical layers 130a, 130b and 130c can be formed with high efficiency.

On the other hand, in the example, the first optical layer 120a and the second optical layer 130a, for instance, form a combination layer, the first optical layer 120b and the second optical layer 130b, for instance, form a combination layer, and the first optical layer 120c and the second optical layer 130c, for instance, form a combination layer, then the anti-reflection composite layer 100 is composed by the three combination layers stacking on each other. However, the present invention is not limited to this, in other examples, anti-reflection composite layer can include 2-6 combination layers formed on the substrate by arc coating so as to achieve the desired anti-reflective effect.

In conclusion, the method for manufacturing anti-reflection composite layer proposed by the present invention is to form the first optical layers and the second optical layers on the substrate by arc coating, and a nanoporous structure can easily be formed through this method, allowing the anti-reflection composite layer to provide a more preferable anti-reflective effect. Compared to conventional sputtering methods, arc coating can form the first optical layers and the second optical layers on the substrate with higher efficiency so as to efficiently provide an anti-reflection composite layer with improved anti-reflective effect.

What is claimed is:

1. An anti-reflection composite layer, including:
a substrate, having a carrier surface;
a plurality of first optical layers, wherein one of the first optical layer is directly disposed on the carrier surface; and
a plurality of second optical layers, alternately arranged with the first optical layers, the first and second optical layers being formed on the carrier surface by a PVD coating process;
wherein refractive index of material forming the first optical layers is higher than refractive index of material forming the second optical layers.

2. The anti-reflection composite layer of claim 1, wherein melting point of the material of the first optical layers falls within the range of 1900-3400 degrees Celsius, whereas the melting point of the materials of the second optical layers falls within the range of 1400-1900 degrees Celsius.

3. The anti-reflection composite layer of claim 1, wherein the material of the first optical layers includes TiO₂, WO₃, Ta₂O₅ or Nb₂O₅;
and the material of the second optical layers includes SiO2.

4. The anti-reflection composite layer of claim 1, wherein the first optical layers and the second optical layers form into a plurality of combination layers, and each of the combination layers is formed by one of the first optical layers and one of the second optical layers, wherein the second optical layer is formed on the side away from the carrier surface, and the numbers of the combination layers fall within the range of 2-6.

5. The anti-reflection composite layer of claim 1, wherein the substrate is flexible glass substrate.

6. The anti-reflection composite layer of claim 1, wherein the thickness of each of the first optical layers falls within the range of 5-150 nanometers in the normal direction of the carrier surface, whereas the thickness of each of the second optical layers falls within of 5-150 nanometers in the normal direction of the carrier surface.

7. A manufacturing method of an anti-reflection composite layer, including:
providing a substrate; and
alternately forming a plurality of first optical layers and a plurality of second optical layers by a PVD coating process on a carrier surface of the substrate, wherein one of the first optical layers is formed directly on the carrier surface of the substrate, and the refractive index of the material of the first optical layers is higher than the refractive index of the material of the second optical layers.

8. The manufacturing method of the anti-reflection composite layer of claim 7, wherein the PVD coating process includes:
adjusting the pressure of a chamber to a pressure range with suction;
placing the substrate into a chamber;
forming an electric arc on the surface of a target, causing the target to provide micro ions; and
depositing the micro ions to form the first optical layer or the second optical layer, wherein the formation of the first optical layer and the second optical layer respectively correspond to targets of different materials.

9. The manufacturing method of the anti-reflection composite layer of claim 8, wherein the pressure range is less than or equal to 0.001 torr.

10. The manufacturing method of the anti-reflection composite layer of claim 8, wherein after the step of adjusting the pressure of the chamber to the pressure range, the manufacturing method further includes:
fill the chamber with oxygen and argon, wherein the ratio of oxygen to argon falls within the range of 1 to 4.

11. The manufacturing method of the anti-reflection composite layer of claim 8, wherein before the step of forming the electric arc on the target, the manufacturing method further includes: form gradient magnetic field on the surface of the target, wherein intensity of the magnetic field at the edge of the target is lower than intensity of the magnetic field in other regions of the target.

12. The manufacturing method of the anti-reflection composite layer of claim 7, wherein the melting point of the material for forming the first optical layers falls within the range of 1900-3400 degrees Celsius, whereas the melting point of the material for forming the second optical layers falls within the range of 1400-1900 degrees Celsius.

13. The manufacturing method of the anti-reflection composite layer of claim 7, wherein the material of the first optical layers include TiO₂, WO₃, Ta₂O₅ or Nb₂O₅;
and the material of the second optical layers include SiO₂.

14. The manufacturing method of the anti-reflection composite layer of claim 7, wherein the first optical layers and the second optical layers form combination layers, each of the combination layers being formed by one of the first optical layers and one of the second optical layers, wherein the second optical layer is formed on the side away from the carrier surface, and numbers of the combination layers fall within the range of 2-6.
